(19) United States
(12) Patent Application Publication
(10) Pub. No.: US 2006/0097614 A1
(43) Pub. Date: May 11, 2006

(54) Organic electroluminescent device and organic electroluminescent apparatus comprising the same

(76) Inventor: Masaya Nakai, Anpachi-gun (JP)

Correspondence Address: MCDERMOTT WILL & EMERY LLP, 600 13TH STREET, N.W., WASHINGTON, DC, 20005-3096, US

(21) Appl. No.: 11/215,116

(22) Filed: Aug. 31, 2005

(30) Foreign Application Priority Data
Aug. 31, 2004 (JP) 2004-253044

(51) Int. Cl. H01L 51/52; H05B 33/02

(52) U.S. Cl. 313/112; 313/506; 313/504; 257/98; 257/E51.022; 428/917

(57) ABSTRACT

An organic EL device comprises a hole injection electrode, a hole injection layer, a hole transport layer, an orange light emitting layer, a blue light emitting layer, an electron transport layer, and an electron injection electrode. A blue color filter layer is disposed below the organic EL device. The ratio of a second peak intensity at a longer wavelength to a first peak intensity at a shorter wavelength in the blue wavelength range is set to not more than 0.73 by adjusting an optical thickness from the hole injection electrode to the electron transport layer.

### BACKGROUND OF THE INVENTION

1. Field of the Invention

The present invention relates to organic electroluminescent devices and organic electroluminescent apparatuses comprising the organic electroluminescent devices.

2. Description of the Background Art

With the recent prosperity of information technology (IT), a need has grown for thin-type display devices as thin as several mm, and capable of providing a full color display. As such thin-type display devices, organic electroluminescent (hereinafter referred to as organic EL) devices have been developed.

As the means for realizing a full color display, there can be mentioned a method using red, green, and blue light emitting devices, and a method using white light emitting devices in combination with color filters that transmit the monochrome colors of three primary colors of light. Such a white light emitting device includes a blue light emitting material and an orange light emitting material to realize white color of light by simultaneously emitting the blue and orange light emitting materials (refer to JP 2001-52870 A, for example).

For practical use of organic EL apparatuses using these white light emitting devices, reducing the power consumption is one of the important issues.

The development of a variety of materials for use inorganic EL devices has heretofore been made for reducing the power consumption of organic EL apparatuses. However, it is required that the power consumption be further reduced.

### SUMMARY OF THE INVENTION

It is an object of the invention to provide organic electroluminescent devices having reduced power consumption and organic electroluminescent apparatuses comprising such organic electroluminescent devices.

The inventor found that it is possible to reduce the power consumption of organic EL devices by optimizing the configuration thereof, other than the method of reducing the power consumption through the development of organic materials.

(1)

An organic electroluminescent device according to one aspect of the invention sequentially comprises an optically transparent first electrode, an organic layer including a light emitting layer that produces light in a wavelength range from at least 400 nm to 530 nm, and a second electrode, wherein a spectrum of the light produced by the light emitting layer has a maximum emission intensity at a first wavelength in a wavelength range from not less than 400 nm and not more than 530 nm, and when the emission intensity at the first wavelength is defined as a first emission intensity, and a maximum emission intensity in a wavelength range from a wavelength 25 nm longer than the first wavelength to 530 nm is defined as a second emission intensity, an optical thickness of the organic layer and an optical thickness of the first electrode are set so that the ratio of the second emission intensity to the first emission intensity is not more than 0.73.

In the organic electroluminescent device, the ratio of the second emission intensity in the longer wavelength range to the first emission intensity in the shorter wavelength range within the wavelength range from 400 nm to 530 nm is set to not more than 0.73. This suppresses the emission in the wavelength range from a wavelength 25 nm longer than the first wavelength to 530 nm, so as to reduce the energy used for the emission in the wavelength range from a wavelength 25 nm longer than the first wavelength to 530 nm. As a result, the power consumption of the organic electroluminescent device can be reduced.

(2)

The organic layer may further include another light emitting layer having a maximum emission intensity in a wavelength range not less than 530 nm. The combination of the emission in the wavelength range from 400 nm to 530 nm and the emission in the wavelength range not less than 530 nm provides emission of a desired color.

(3)

An organic electroluminescent apparatus according to another aspect of the invention comprises one or a plurality of organic electroluminescent devices, and one or a plurality of color conversion members that transmit light produced by the one or plurality of organic electroluminescent devices, wherein each of the one or plurality of organic electroluminescent devices sequentially comprises an optically transparent first electrode, an organic layer including a light emitting layer that produces light in a wavelength range from at least 400 nm to 530 nm, and a second electrode, wherein a spectrum of the light produced by the light emitting layer has a maximum emission intensity at a first wavelength in a wavelength range from not less than 400 nm and not more than 530 nm, and when the emission intensity at the first wavelength is defined as a first emission intensity, and a maximum emission intensity in a wavelength range from a wavelength 25 nm longer than the first wavelength to 530 nm is defined as a second emission intensity, an optical thickness of the organic layer and an optical thickness of the first electrode are set so that the ratio of the second emission intensity to the first emission intensity is not more than 0.73, and wherein at least one of the color conversion members transmits light in a wavelength range not less than 400 nm and not more than 530 nm.

The light produced by the one or plurality of organic electroluminescent devices is emitted out of the organic electroluminescent apparatus via the one or plurality of color conversion members. Also, the use of the above-described organic electroluminescent devices suppresses the emission in the wavelength range from a wavelength 25 nm longer than the first wavelength to 530 nm. This reduces the energy used for the emission in the wavelength range from a wavelength 25 nm longer than the first wavelength to 530 nm.

Moreover, at least one of the color conversion members transmits light in the wavelength range not less than 400 nm and not more than 530 nm, so that blue light is extracted out of the organic electroluminescent apparatus. As a result, the power consumption of the organic electroluminescent apparatus can be reduced while blue light with high color purity can be obtained.

(4)

The organic layer may further include another light emitting layer having a maximum emission intensity in a wavelength range not less than 530 nm. The combination of the emission in the wavelength range from 400 nm to 530 nm and the emission in the wavelength range not less than 530 nm provides emission of a desired color.

(5)

The at least one color conversion member may have a transmittance at a wavelength having the second emission intensity lower than a transmittance at the first wavelength. This allows the color purity of the blue light to be further increased.

(6)

An organic electroluminescent apparatus according to still another aspect of the invention comprises an optically transparent substrate, one or a plurality of organic electroluminescent devices provided on the optically transparent substrate, and one or a plurality of color conversion members provided between the optically transparent substrate and the one or plurality of organic electroluminescent devices, wherein each of the one or plurality of organic electroluminescent devices sequentially comprises an optically transparent first electrode, an organic layer including a light emitting layer that produces light in a wavelength range from at least 400 nm to 530 nm, and a second electrode, wherein a spectrum of the light produced by the light emitting layer has a maximum emission intensity at a first wavelength in a wavelength range from not less than 400 nm and not more than 530 nm, and when the emission intensity at the first wavelength is defined as a first emission intensity, and a maximum emission intensity in a wavelength range from a wavelength 25 nm longer than the first wavelength to 530 nm is defined as a second emission intensity, an optical thickness of the organic layer and an optical thickness of the first electrode are set so that the ratio of the second emission intensity to the first emission intensity is not more than 0.73, and wherein at least one of the color conversion members transmits light in a wavelength range not less than 400 nm and not more than 530 nm.

The light produced by the one or plurality of organic electroluminescent devices is emitted out of the organic electroluminescent apparatus via the one or plurality of color conversion members and the optically transparent substrate. Also, the use of the above-described organic electroluminescent devices suppresses the emission in the wavelength range from a wavelength 25 nm longer than the first wavelength to 530 nm. This reduces the energy used for the emission in the wavelength range from a wavelength 25 nm longer than the first wavelength to 530 nm.

Moreover, at least one of the color conversion members transmits light in the wavelength range not less than 400 nm and not more than 530 nm, so that blue light is extracted out of the organic electroluminescent apparatus. As a result, the organic electroluminescent apparatus with a back emission structure is realized in which the power consumption is reduced, and blue light with high color purity is obtained.

(7)

The organic layer may further include another light emitting layer having a maximum emission intensity in a wavelength range not less than 530 nm. The combination of the emission in the wavelength range from 400 nm to 530 nm and the emission in the wavelength range not less than 530 nm provides emission of a desired color.

(8)

The at least one color conversion member may have a transmittance at a wavelength having the second emission intensity lower than a transmittance at the first wavelength. This allows the color purity of the blue light to be further increased.

(9)

An organic electroluminescent apparatus according to yet another aspect of the invention comprises a substrate, one or a plurality of organic electroluminescent devices provided on the substrate, and one or a plurality of color conversion members provided on the one or plurality of organic electroluminescent devices, wherein each of the one or plurality of organic electroluminescent devices sequentially comprises an optically transparent first electrode, an organic layer including a light emitting layer that produces light in a wavelength range from at least 400 nm to 530 nm, and a second electrode, wherein a spectrum of the light produced by the light emitting layer has a maximum emission intensity at a first wavelength in a wavelength range from not less than 400 nm and not more than 530 nm, and when the emission intensity at the first wavelength is defined as a first emission intensity, and a maximum emission intensity in a wavelength range from a wavelength 25 nm longer than the first wavelength to 530 nm is defined as a second emission intensity, an optical thickness of the organic layer and an optical thickness of the first electrode are set so that the ratio of the second emission intensity to the first emission intensity is not more than 0.73, and wherein at least one of the color conversion members transmits light in a wavelength range not less than 400 nm and not more than 530 nm.

The light produced by the one or plurality of organic electroluminescent devices is emitted out of the organic electroluminescent apparatus via the one or plurality of color conversion members. Also, the use of the above-described organic electroluminescent devices suppresses the emission in the wavelength range from a wavelength 25 nm longer than the first wavelength to 530 nm. This reduces the energy used for the emission in the wavelength range from a wavelength 25 nm longer than the first wavelength to 530 nm.

Moreover, at least one of the color conversion members transmits light in the wavelength range not less than 400 nm and not more than 530 nm, so that blue light is extracted out of the organic electroluminescent apparatus. As a result, the organic electroluminescent apparatus with a top emission structure is realized in which the power consumption is reduced, and blue light with high color purity is obtained.

(10)

The organic layer may further include another light emitting layer having a maximum emission intensity in a wavelength range not less than 530 nm. The combination of the emission in the wavelength range from 400 nm to 530 nm and the emission in the wavelength range not less than 530 nm provides emission of a desired color.

(11)

The at least one color conversion member may have a transmittance at a wavelength having the second emission intensity lower than a transmittance at the first wavelength. This allows the color purity of the blue light to be further increased.

According to the invention, the power consumption of organic electroluminescent devices and organic electroluminescent apparatuses can be reduced by setting the optical thickness of the organic layer and the optical thickness of the first electrode so that the ratio of the second emission intensity to the first emission intensity is not more than 0.73 in the wavelength region from 400 nm to 530 nm.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross section showing an organic EL apparatus according to an embodiment of the invention;

FIG. 2 is a detailed cross section showing the configuration of the organic EL apparatus in FIG. 1;

FIG. 3 is a diagram showing an example of the emission spectrum of an organic EL device according to the embodiment;

FIG. 4 is a detailed cross section showing an organic EL apparatus according to another embodiment of the invention;

FIG. 5 is a graph showing the emission spectra of organic EL devices in Inventive Examples 1 to 4 and Comparative Examples 1 to 3; and

FIG. 6 is a diagram showing the relationship between the peak ratio and the power consumption of each of the organic EL devices in Inventive Examples 1 to 4 and Comparative Examples 1 to 3.

### DESCRIPTION OF THE PREFERRED EMBODIMENTS

Organic electroluminescent (hereinafter referred to as organic EL) devices according to the invention and organic EL apparatuses comprising the organic EL devices will hereinafter be described with reference to the drawings.

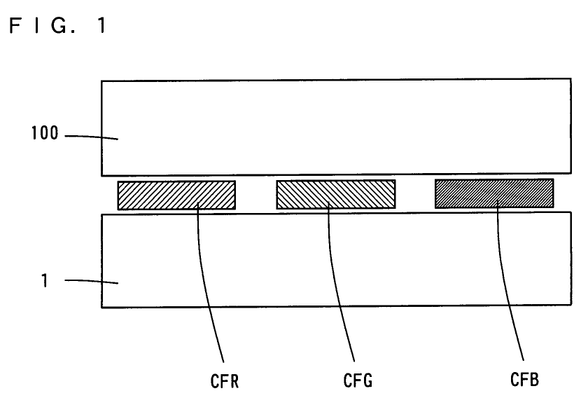

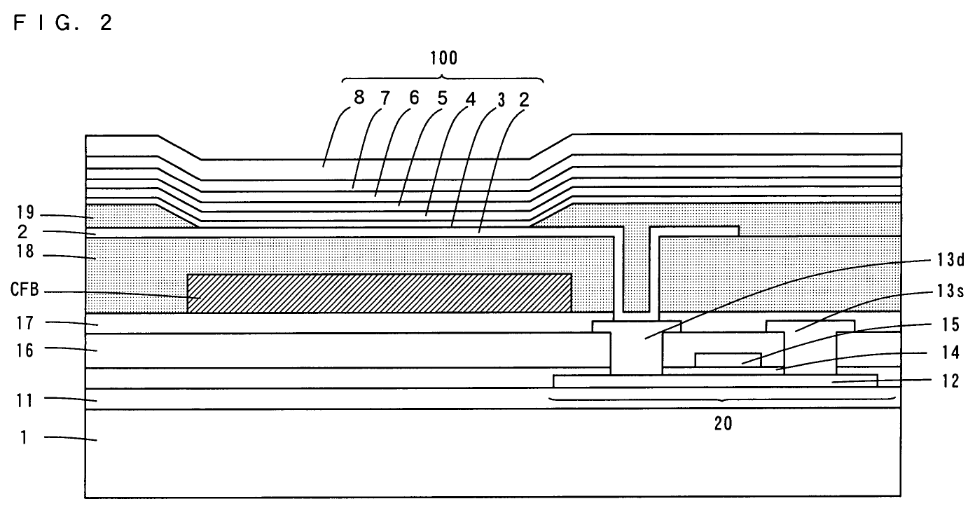

FIG. 1 is a schematic cross section showing an example of an organic EL apparatus according to an embodiment, and FIG. 2 is a detailed cross section of the configuration of the organic EL apparatus in FIG. 1.

The organic EL apparatus in FIG. 1 comprises an organic EL device 100, a red color filter layer CFR, a green color filter layer CFG, a blue color filter layer CFB, and a substrate 1.

The red color filter layer CFR, the green color filter layer CFG, and the blue color filter layer CFB are formed between the organic EL device 100 and the substrate 1. The red color filter layer CFR, the green color filter layer CFG, and the blue color filter layer CFB are disposed to form each pixel of the organic EL apparatus.

Each of these color filter layers is composed of a transparent material such as glass or plastic, for example. Alternatively, a color conversion medium (CCM) may be used or both of a transparent material such as glass or plastic and a CCM may be used as each color filter layer.

Referring now to FIG. 2, the configuration of the organic EL apparatus in FIG. 1 is described in detail.

As shown in FIG. 2, a laminated film 11 that includes, e.g., a layer composed of silicon oxide (SiO₂) and a layer composed of silicon nitride (SiNₓ) is formed on a transparent substrate 1 of glass, plastic or the like.

A thin film transistor (TFT) 20 is formed on a portion of the laminated film 11. The TFT 20 is composed of a channel region 12, a drain electrode 13d, a source electrode 13s, a gate oxide film 14, and a gate electrode 15.

The channel region 12 composed of a polysilicon layer or the like is formed on, e.g., a portion of the laminated film 11. The drain electrode 13d and the source electrode 13s are formed on the channel region 12. The gate oxide film 14 is formed on the channel region 12. The gate electrode 15 is formed on the gate oxide film 14.

The drain electrode 13d of the TFT 20 is connected to a hole injection electrode 2 mentioned below, and the source electrode 13s of the TFT 20 is connected to a power supply line (not shown).

A first interlayer insulating film 16 is formed on the gate oxide film 14 so as to cover the gate electrode 15. A second interlayer insulating film 17 is formed on the first interlayer insulating film 16 so as to cover the drain electrode 13d and the source electrode 13s. The gate electrode 15 is connected to an electrode (not shown).

The gate oxide film 14 has a laminated structure that includes, e.g., a layer composed of silicon nitride and a layer composed of silicon oxide. The first interlayer insulating film 16 has a laminated structure that includes, e.g., a layer composed of silicon oxide and a layer composed of silicon nitride, and the second interlayer insulating film 17 is composed of, e.g., silicon nitride.

Each of the red color filter layer CFR, the green color filter layer CFG, and the blue color filter layer CFB is formed on the second interlayer insulating film 17. The red color filter layer CFR transmits light in the red wavelength range, the green color filter layer CFG transmits light in the green wavelength range, and the blue color filter layer CFB transmits light in the blue wavelength range. The blue color filter layer CFB is illustrated in FIG. 2. The blue color filter layer CFB preferably transmits not less than 70% of the light in a wavelength range from 400 nm to 530 nm, more preferably not less than 80%.

A first planarization layer 18 composed of, e.g., acrylic resin is formed on the second interlayer insulating film 17 so as to cover the red color filter layer CFR, the green color filter layer CFG, and the blue color filter layer CFB.

An organic EL device 100 is formed on the first planarization layer 18. The organic EL device 100 includes, in order, a hole injection electrode 2, a hole injection layer 3, a hole transport layer 4, an orange light emitting layer 5, a blue light emitting layer 6, an electron transport layer 7, and an electron injection electrode 8. The hole injection electrode 2 is formed on the first planarization layer 18 for each pixel, and the insulating second planarization layer 19 is formed between pixels so as to cover the hole injection electrode 2. The hole injection electrode 2 is composed of a transparent conductive film, such as indium-tin oxide (ITO) or the like.

The hole injection layer 3 is formed so as to cover the hole injection electrode 2 and the second planarization layer 19. The hole injection layer 3 is composed of, e.g., CFₓ (fluorocarbon) formed by a plasma chemical vapor deposition (CVD) method.

On top of this hole injection layer 3, the hole transport layer 4, the orange light emitting layer 5, the blue light emitting layer 6, and the electron transport layer 7 are formed in order. The electron injection electrode 8 composed of, e.g., aluminum is formed on the electron transport layer 7.

The hole transport layer 4 is composed of an organic material such as, e.g., N,N′-Di(naphthalene-1-yl)-N,N′-diphenyl-benzidine (hereinafter abbreviated to NPB) represented by the formula (1) shown below:

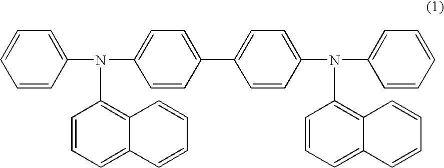

The orange light emitting layer 5 is composed of a host material and an emissive dopant doped into the host material.

For example, NPB may be used as the host material of the orange light emitting layer 5.

For example, 5,12-Bis(4-(6-methylbenzothiazol-2-yl)phenyl)-6,11-diphenylnaphthacene (hereinafter abbreviated to DBZR) represented by the formula (2) shown below may be used as the emissive dopant of the orange light emitting layer 5.

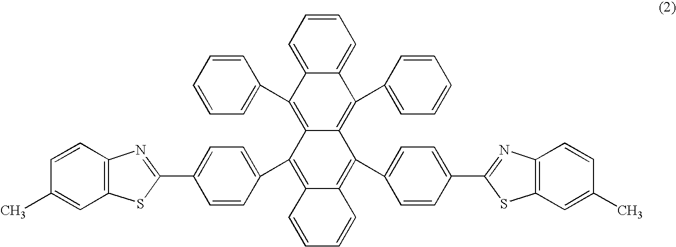

The blue light emitting layer 6 is composed of a host material and first and second dopants doped into the host material. The second dopant emits light, and the first dopant plays the role in assisting the emission of the second dopant by encouraging the transfer of energy from the host material to the second dopant.

For example, tert-butyl substituted dinaphthylanthracene (hereinafter abbreviated to TBADN) represented by the formula (3) shown below may be used as the host material of the blue light emitting layer 6.

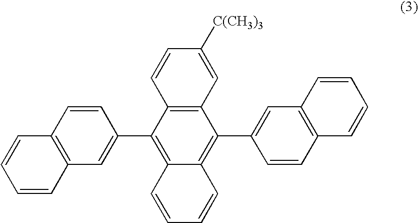

For example, NPB may be used as the first dopant of the blue light emitting layer 6.

For example, 1,4,7,10-tetra-tert-butylperylene (hereinafter abbreviated to TBP) represented by the formula (4) shown below may be used as the second dopant of the blue light emitting layer 6.

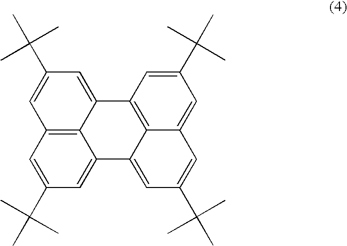

For example, 2,9-dimethyl-4,7-diphenyl-1,10-phenanthroline (hereinafter abbreviated to BCP) represented by the formula (5) shown below may be used as the electron transport layer 7. In this case, high electron mobility of BCP enables efficient injection of electrons into the blue light emitting layer 6 and the orange light emitting layer 5. This reduces the drive voltage to lower the power consumption of the organic EL device 100.

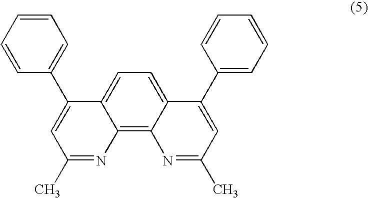

Alternatively, other organic material such as tris(8-hydroxyquinolinato)aluminum (hereinafter abbreviated to Alq₃) represented by the formula (6) shown below may be used as the electron transport layer 7.

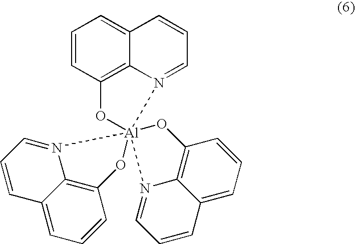

When a voltage is applied across the above-described organic EL device 100, i.e., between the hole injection electrode 2 and the electron injection electrode 8, holes are injected from the hole injection electrode 2, and electrons are injected from the electron injection electrode 8. The holes are transported via the hole transport layer 4 into the orange light emitting layer 5 and the blue light emitting layer 6, and the electrons are transported via the electron transport layer 7 into the blue light emitting layer 6 and the orange light emitting layer 5. When the holes and electrons are recombined in the orange light emitting layer 5 and the blue light emitting layer 6, the orange light emitting layer 5 and the blue light emitting layer 6 emit light. As a result, white light is obtained.

As described above, the laminated film 11, the TFT 20, the first interlayer insulating film 16, the second interlayer insulating film 17, the red color filter layer CFR, the green color filter layer CFG, the blue color filter layer CFB, the first planarization layer 18, the second planarization layer 19, and the organic EL device 100 are formed on the substrate 1. This results in the organic EL apparatus with a back emission structure.

Light produced by the organic EL device 100 is extracted out of the organic EL apparatus via the red color filter layer CFR, the green color filter layer CFG, the blue color filter layer CFB, and the transparent substrate 1.

The transmission of white light from the above-described organic EL device 100 through the blue color filter layer CFB is now described.

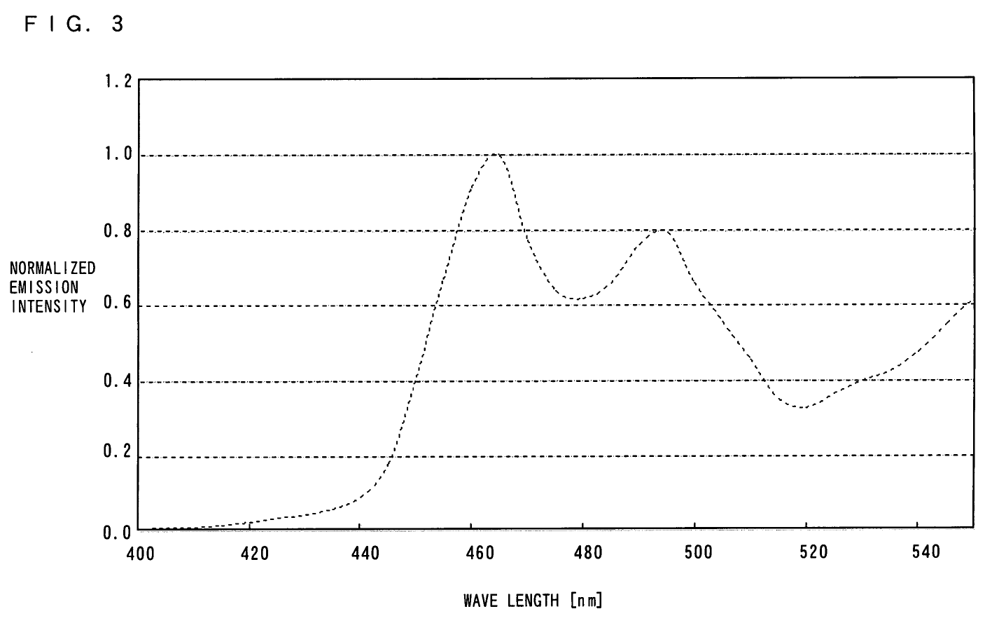

FIG. 3 is a diagram showing an example of the emission spectrum of the above-described organic EL device. In FIG. 3, the abscissa represents wavelength, and the ordinate represents normalized emission intensity. In FIG. 3, the emission intensity at each wavelength is normalized so that the maximum value of emission intensity is one.

As shown in FIG. 3, the emission spectrum of the organic EL device 100 has a first peak in a wavelength range from 400 to 480 nm and a second peak in a wavelength range from 480 to 530 nm within the blue wavelength range (400 to 530 nm).

When the blue color filter layer CFB is provided to the organic EL device 100 having such an emission spectrum as shown in FIG. 3, light of wavelengths except in the blue wavelength range, in general, hardly passes through the blue color filter layer CFB. For increasing the purity of blue light, in particular, a blue color filter layer CFB is used that exhibits a high transmittance (for example not less than about 80%) at the wavelength of a first peak and in its peripheral wavelength range, and a low transmittance (for example not more than about 70%) in the other wavelength range. The use of such a blue color filter layer CFB results in a waste of energy used for the emission in the low transmittance wavelength range. The inventor found that the power consumption of the organic EL device 100 can be reduced by suppressing such wasteful emission in this wavelength range.

In the embodiment, the emission intensity is suppressed in a range of wavelengths longer than the wavelength at the first peak by not less than 25 nm in the blue wavelength range. More specifically, the ratio of the second peak intensity to the first peak intensity is set to not more than 0.73.

It should be noted here that the emission spectrum of the organic EL device 100 varies depending on the material and/or the thickness of each layer. In this embodiment, the ratio of the second peak intensity to the first peak intensity is set to not more than 0.73 by adjusting an optical thickness (i.e., integral of thickness and refractive index) from the hole injection electrode 2 to the electron transport layer 7 to control the effect of optical interference. This suppresses the wasteful emission in the aforementioned portion of the wavelength range to reduce the power consumption of the organic EL device 100.

Note that the material for use in each layer of the organic EL device 100 is not limited to those described above. With other materials also, the ratio of the second peak intensity to the first peak intensity in the blue wavelength range is set to not more than 0.73 by adjusting the optical thickness from the hole injection electrode 2 to the electron transport layer 7 in the organic EL device 100. In this way, the power consumption of the organic EL device 100 can be reduced.

In the above-described embodiment, the hole injection electrode 2 corresponds to a first electrode; the hole injection layer 3, the hole transport layer 4, the orange light emitting layer 5, the blue light emitting layer 6, and the electron transport layer 7 correspond to an organic layer; and the electron injection electrode 8 corresponds to a second electrode.

The red color filter layer CFR, the green color filter layer CFG, and the blue color filter layer CFB correspond to one or a plurality of color conversion members.

The organic EL apparatus according to the embodiment may also have the configuration as shown below.

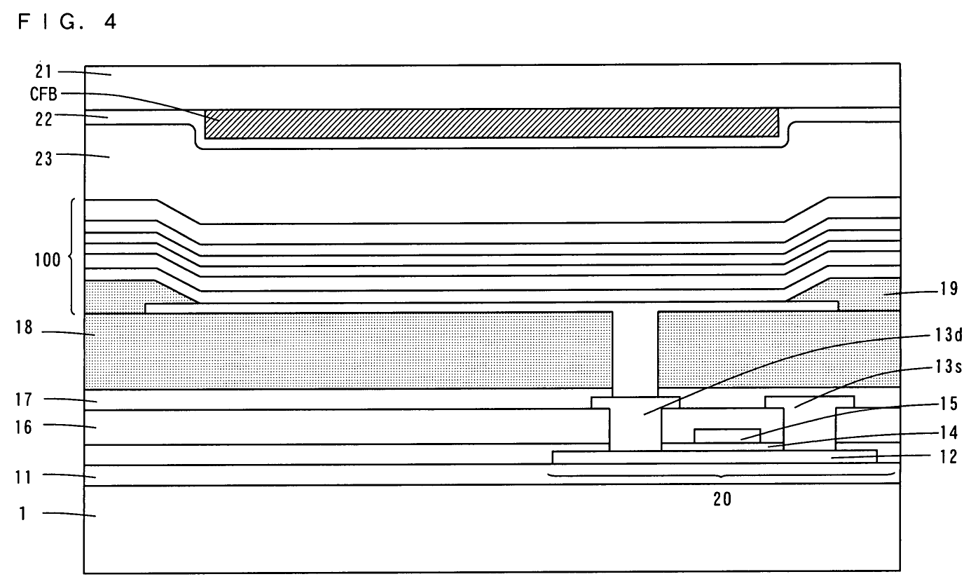

FIG. 4 is a detailed cross section showing an organic EL apparatus according to another embodiment. The configuration of the organic EL apparatus in FIG. 4 is different from that of the organic EL apparatus in FIG. 2 as follows.

Similarly to the organic EL apparatus in FIG. 2, a laminated film 11, a TFT 20, a first interlayer insulating film 16, a second interlayer insulating film 17, a blue color filter layer CFB, a first planarization layer 18, a second planarization layer 19, and an organic EL device 100 are formed on a substrate 1 in the organic EL apparatus in FIG. 4. In FIG. 4 also, the blue color filter layer CFB is illustrated.

After that, a laminate that includes, in order, an overcoat layer 22, a blue color filter layer CFB, and a transparent sealing substrate 21 is bonded on the organic EL device 100 through a transparent adhesive layer 23. This results in the organic EL apparatus with a top emission structure.

Light produced by the organic EL device 100 is extracted out of the organic EL apparatus via the red color filter layer CFR, the green color filter layer CFG, the blue color filter layer CFB, and the transparent sealing substrate 21.

The substrate 1 in the organic EL apparatus in FIG. 4 may be formed of an opaque material. The hole injection electrode 2 of the organic EL device 100 is formed by laminating, e.g., about 50-nm thick indium-tin oxide (ITO) and about 100-nm thick aluminum, chromium or silver. In this case, the hole injection electrode 2 reflects the light produced by the organic EL device 100 toward the sealing substrate 21.

The electron injection electrode 8 is composed of a transparent material. The electron injection electrode 8 is formed by laminating, e.g., about 100-nm thick indium-tin oxide (ITO) and about 20-nm thick silver.

The overcoat layer 22 is formed of, e.g., about 1-μm thick acrylic resin. Each of the red color filter layer CFR, the green color filter layer CFG, and the blue color filter layer CFB has a thickness of about 1 μm.

A glass, a layer composed of silicon oxide (SiO₂) or a layer composed of silicon nitride (SiNₓ), for example, may be used as the sealing substrate 21.

Since the organic EL apparatus in FIG. 4 has a top emission structure, a region above the TFT 20 can also be used as a pixel area. That is, the blue color filter layer CFB larger than the blue color filter layer CFB in FIG. 2 can be used in the organic EL apparatus in FIG. 4. This enables the use of a wider region as a pixel area, thereby improving the luminescent efficiency of the organic EL apparatus.

In the organic EL apparatus in FIG. 4, the ratio of the second peak intensity to the first peak intensity in the blue wavelength range is set to not more than 0.73 by adjusting an optical thickness from the hole injection layer 3 to the electron injection electrode 8 of the organic EL device 100. This allows the power consumption of the organic EL device to be reduced.

In the above-described embodiment, the electron injection electrode 8 corresponds to a first electrode, and the hole injection electrode 2 corresponds to a second electrode.

### EXAMPLES

It will be demonstrated by way of Examples that the invention enables reduced power consumption by adjusting optical thicknesses of organic EL devices.

### Inventive Example 1

In Inventive Example 1, an organic EL device having the configuration of FIG. 2 was fabricated as follows.

The hole injection electrode 2 is composed of 30-nm thick indium-tin oxide (ITO) with a refractive index of 1.97. The hole injection layer 3 is composed of CFₓ (fluorocarbon).

The hole transport layer 4 is composed of 110-nm thick NPB with a refractive index of 1.85. The orange light emitting layer 5 having a thickness of 60 nm is formed by adding 3% by volume of an emissive dopant with a refractive index of 1.9 into a host material composed of NPB with a refractive index of 1.85. The blue light emitting layer 6 having a thickness of 50 nm is formed by adding 16% by volume of a first dopant composed of NPB with a refractive index of 1.85 and a 1% by volume of a second dopant composed of TBP with a refractive index of 1.85 into a host material with a refractive index of 1.9. The electron transport layer 7 is composed of a 10-nm thick material with a refractive index of 1.8.

The electron injection electrode 8 is composed of a laminated structure that includes a 1-nm thick lithium fluoride (LiF) film and a 400-nm thick aluminum film.

In this way, the organic EL device in Inventive Example 1 was fabricated. The optical thickness of the organic EL device in Inventive Example 1 from the hole injection electrode 2 to the electron transport layer 7 was 484 nm.

### Inventive Example 2

In Inventive Example 2, an organic EL device similar to that in Inventive Example 1 was fabricated except setting the thickness of the hole transport layer 4 to 130 nm. The optical thickness of the organic EL device in Inventive Example 2 from the hole injection electrode 2 to the electron transport layer 7 was 521 nm.

### Inventive Example 3

In Inventive Example 3, an organic EL device similar to that in Inventive Example 1 was fabricated except setting the thickness of the hole transport layer 4 to 90 nm. The optical thickness of the organic EL device in Inventive Example 3 from the hole injection electrode 2 to the electron transport layer 7 was 447 nm.

### Inventive Example 4

In Inventive Example 4, an organic EL device similar to that in Inventive Example 1 was fabricated except setting the thickness of the hole transport layer 4 to 210 nm. The optical thickness of the organic EL device in Inventive Example 4 from the hole injection electrode 2 to the electron transport layer 7 was 669 nm.

### Comparative Example 1

In Comparative Example 1, an organic EL device similar to that in Inventive Example 1 was fabricated except setting the thickness of the hole transport layer 4 to 150 nm. The optical thickness of the organic EL device in Comparative Example 1 from the hole injection electrode 2 to the electron transport layer 7 was 558 nm.

### Comparative Example 2

In Comparative Example 2, an organic EL device similar to that in Inventive Example 1 was fabricated except setting the thickness of the hole transport layer 4 to 190 nm. The optical thickness of the organic EL device in Comparative Example 2 from the hole injection electrode 2 to the electron transport layer 7 was 632 nm.

### Comparative Example 3

In Comparative Example 3, an organic EL device similar to that in Inventive Example 1 was fabricated except setting the thickness of the hole transport layer 4 to 170 nm. The optical thickness of the organic EL device in Inventive Example 3 from the hole injection electrode 2 to the electron transport layer 7 was 595 nm.

(Evaluation)

The organic EL devices thus fabricated in Inventive Examples 1 to 4 and Comparative Examples 1 to 3 were measured at 30 mA/cm² for emission spectrum and power consumption. Measurements were performed at room temperature.

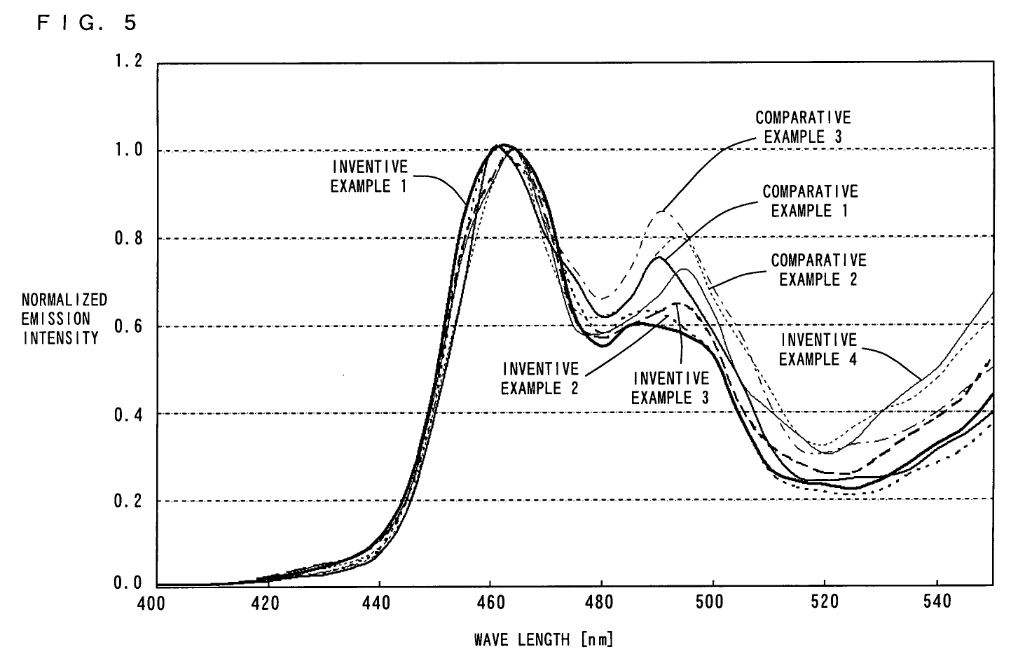

FIG. 5 is a graph showing the emission spectra of the organic EL devices in Inventive Examples 1 to 4 and Comparative Examples 1 to 3. In FIG. 5, the abscissa represents wavelength, and the ordinate represents normalized emission intensity. In FIG. 5, for the emission spectrum in the blue wavelength range of each of the organic EL devices in Inventive Examples 1 to 4 and Comparative Examples 1 to 3, the emission intensity of a peak having a highest emission intensity is defined as one, and the other emission intensities are normalized accordingly.

As shown in FIG. 5, the emission spectrum of each of the organic EL devices in Inventive Examples 1 to 4 and Comparative Examples 1 to 3 has a first peak in a wavelength range from 400 to 480 nm and a second peak in a wavelength range from 480 to 530 nm within the blue wavelength range.

Table 1 shows the conditions, the optical thickness, and the peak ratio of each of the layers. The peak ratio herein represents the ratio of a second peak to a first peak.

TABLE 1

| | | | ORANGE LIGHT | | | | | | | |
|---|---|---|---|---|---|---|---|---|---|---|
| | | | EMITTING LAYER | | BLUE LIGHT | | | | | |
| | | HOLE | | AMOUNT | EMITTING LAYER | | | | | |
| | HOLE | TRANS- | | OF | | AMOUNT | AMOUNT | | | |
| | INJETION | PORT | | ADDED | | OF | OF | ELECTRON | OPTICAL | |
| | ELECTRODE | LAYER | THICK- | EMISSIVE | THICK- | ADDED | ADDED | TRANSPORT | THICKNESS | |
| | (ITO) | (NPB) | NESS | DOPANT | NESS | NPB | TPB | LAYER | nd | PEAK |
| | [nm] | [nm] | [nm] | [%] | [nm] | [%] | [%] | [nm] | [nm] | RATIO |
| INVENTIVE | 30 | 110 | 60 | 3 | 50 | 16 | 1 | 10 | 484 | 0.60 |
| EXAMPLE 1 | | | | | | | | | | |
| INVENTIVE | 30 | 130 | 60 | 3 | 50 | 16 | 1 | 10 | 521 | 0.63 |
| EXAMPLE 2 | | | | | | | | | | |
| INVENTIVE | 30 | 90 | 60 | 3 | 50 | 16 | 1 | 10 | 447 | 0.65 |
| EXAMPLE 3 | | | | | | | | | | |
| INVENTIVE | 30 | 210 | 60 | 3 | 50 | 16 | 1 | 10 | 669 | 0.73 |
| EXAMPLE 4 | | | | | | | | | | |
| COMPARATIVE | 30 | 150 | 60 | 3 | 50 | 16 | 1 | 10 | 558 | 0.75 |
| EXAMPLE 1 | | | | | | | | | | |
| COMPARATIVE | 30 | 190 | 60 | 3 | 50 | 16 | 1 | 10 | 632 | 0.80 |
| EXAMPLE 2 | | | | | | | | | | |
| COMPARATIVE | 30 | 170 | 60 | 3 | 50 | 16 | 1 | 10 | 595 | 0.86 |
| EXAMPLE 3 | | | | | | | | | | |

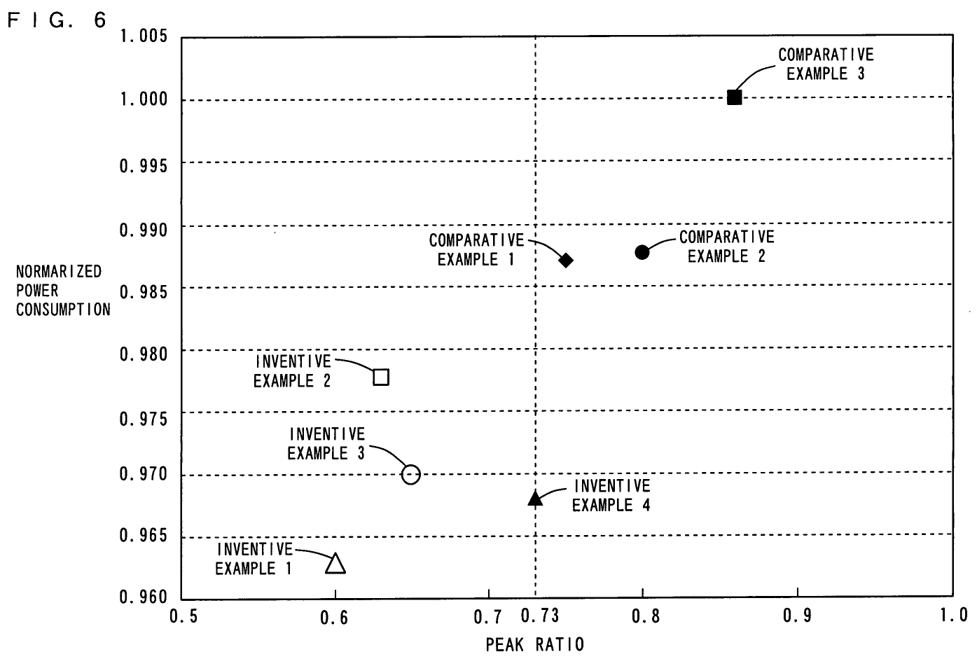

FIG. 6 is a diagram showing the relationship between the peak ratio and the power consumption of each of the organic EL devices in Inventive Examples 1 to 4 and Comparative Examples 1 to 3. In FIG. 6, the abscissa represents peak ratio, and the ordinate represents normalized power consumption. In FIG. 6, the power consumption of the organic EL device in Comparative Example 3 is defined as one, and the power consumptions for Inventive Examples 1 to 4 and Comparative Example 1, 2 are normalized accordingly.

As shown in FIG. 6, the power consumptions of the organic EL devices in Inventive Examples 1 to 4 are lower than those of the organic EL devices in Comparative Examples 1 to 3.

The peak ratios of the organic EL devices in Inventive Examples 1 to 4 are smaller than those of the organic EL devices in Comparative Examples 1 to 3. At peak ratios of not more than 0.73, the power consumptions are abruptly reduced. This is because, when the peak ratio is set to not more than 0.73, the energy used for the emission at the second peak is reduced. Consequently, with the organic EL devices in Inventive Examples 1 to 4 having peak ratios of not more than 0.73, the power consumptions can be lower than those for the organic EL devices in Comparative Examples 1 to 3 having peak ratios over 0.73.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An organic electroluminescent device sequentially comprising:
an optically transparent first electrode;
an organic layer including a light emitting layer that produces light in a wavelength range from at least 400 nm to 530 nm; and
a second electrode, wherein
a spectrum of the light produced by said light emitting layer has a maximum emission intensity at a first wavelength in a wavelength range from not less than 400 nm and not more than 530 nm, and
when the emission intensity at said first wavelength is defined as a first emission intensity, and a maximum emission intensity in a wavelength range from a wavelength 25 nm longer than said first wavelength to 530 nm is defined as a second emission intensity, an optical thickness of said organic layer and an optical thickness of said first electrode are set so that the ratio of said second emission intensity to said first emission intensity is not more than 0.73.

2. The organic electroluminescent device according to claim 1, wherein
said organic layer further includes another light emitting layer having a maximum emission intensity in a wavelength range not less than 530 nm.

3. An organic electroluminescent apparatus comprising:
one or a plurality of organic electroluminescent devices; and
one or a plurality of color conversion members that transmit light produced by said one or plurality of organic electroluminescent devices, wherein
each of said one or plurality of organic electroluminescent devices sequentially comprises:
an optically transparent first electrode;
an organic layer including a light emitting layer that produces light in a wavelength range from at least 400 nm to 530 nm; and
a second electrode, wherein
a spectrum of the light produced by said light emitting layer has a maximum emission intensity at a first wavelength in a wavelength range from not less than 400 nm and not more than 530 nm, and
when the emission intensity at said first wavelength is defined as a first emission intensity, and a maximum emission intensity in a wavelength range from a wavelength 25 nm longer than said first wavelength to 530 nm is defined as a second emission intensity, an optical thickness of said organic layer and an optical thickness of said first electrode are set so that the ratio of said second emission intensity to said first emission intensity is not more than 0.73, and wherein
at least one of said color conversion members transmits light in a wavelength range not less than 400 nm and not more than 530 nm.

4. The organic electroluminescent apparatus according to claim 3, wherein
said organic layer further includes another light emitting layer having a maximum emission intensity in a wavelength range not less than 530 nm.

5. The organic electroluminescent apparatus according to claim 3, wherein
said at least one color conversion member has a transmittance at a wavelength having said second emission intensity lower than a transmittance at said first wavelength.

6. An organic electroluminescent apparatus comprising:
an optically transparent substrate;
one or a plurality of organic electroluminescent devices provided on said optically transparent substrate; and
one or a plurality of color conversion members provided between said optically transparent substrate and said one or plurality of organic electroluminescent devices, wherein
each of said one or plurality of organic electroluminescent devices sequentially comprises:
an optically transparent first electrode;
an organic layer including a light emitting layer that produces light in a wavelength range from at least 400 nm to 530 nm; and
a second electrode, wherein
a spectrum of the light produced by said light emitting layer has a maximum emission intensity at a first wavelength in a wavelength range from not less than 400 nm and not more than 530 nm, and
when the emission intensity at said first wavelength is defined as a first emission intensity, and a maximum emission intensity in a wavelength range from a wavelength 25 nm longer than said first wavelength to 530 nm is defined as a second emission intensity, an optical thickness of said organic layer and an optical thickness of said first electrode are set so that the ratio of said second emission intensity to said first emission intensity is not more than 0.73, and wherein
at least one of said color conversion members transmits light in a wavelength range not less than 400 nm and not more than 530 nm.

7. The organic electroluminescent apparatus according to claim 6, wherein
said organic layer further includes another light emitting layer having a maximum emission intensity in a wavelength range not less than 530 nm.

8. The organic electroluminescent apparatus according to claim 6, wherein
said at least one color conversion member has a transmittance at a wavelength having said second emission intensity lower than a transmittance at said first wavelength.

9. An organic electroluminescent apparatus comprising:
a substrate;
one or a plurality of organic electroluminescent devices provided on said substrate; and
one or a plurality of color conversion members provided on said one or plurality of organic electroluminescent devices, wherein
each of said one or plurality of organic electroluminescent devices sequentially comprises:
an optically transparent first electrode;
an organic layer including a light emitting layer that produces light in a wavelength range from at least 400 nm to 530 nm; and
a second electrode, wherein
a spectrum of the light produced by said light emitting layer has a maximum emission intensity at a first wavelength in a wavelength range from not less than 400 nm and not more than 530 nm, and
when the emission intensity at said first wavelength is defined as a first emission intensity, and a maximum emission intensity in a wavelength range from a wavelength 25 nm longer than said first wavelength to 530 nm is defined as a second emission intensity, an optical thickness of said organic layer and an optical thickness of said first electrode are set so that the ratio of said second emission intensity to said first emission intensity is not more than 0.73, and wherein
at least one of said color conversion members transmits light in a wavelength range not less than 400 nm and not more than 530 nm.

10. The organic electroluminescent apparatus according to claim 9, wherein
said organic layer further includes another light emitting layer having a maximum emission intensity in a wavelength range not less than 530 nm.

11. The organic electroluminescent apparatus according to claim 9, wherein
said at least one color conversion member has a transmittance at a wavelength having said second emission intensity lower than a transmittance at said first wavelength.
